(19) United States
(12) Patent Application Publication
(10) Pub. No.: US 2014/0272217 A1
(43) Pub. Date: Sep. 18, 2014

(54) METHODS AND STRUCTURES FOR THERMAL MANAGEMENT IN AN ELECTRONIC DEVICE

(71) Applicant: APPLE INC., Cupertino, CA (US)

(72) Inventors: Douglas J. WEBER, Arcadia, CA (US); Naoto MATSUYUKI, Kasugai (JP)

(73) Assignee: Apple Inc., Cupertino, CA (US)

(21) Appl. No.: 13/865,102

(22) Filed: Apr. 17, 2013

Related U.S. Application Data
(60) Provisional application No. 61/803,052, filed on Mar. 18, 2013.

(51) Int. Cl. H05K 7/20; H05K 13/00

(52) U.S. Cl. CPC H05K 7/20409; H05K 13/00
USPC 428/34.6; 427/58

(57) ABSTRACT

The described embodiments relate generally to a structure and methods of forming a structure for improving thermal management in an electronic device. The structure including a casing; a cover glass; a multilayer film on an exterior surface of the casing and of the cover glass, adapted to reflect radiation in a first spectral region and to transmit radiation in a second spectral region. In embodiments consistent with the present disclosure a casing for a portable electronic device may include a reflective portion in an interior surface including a hot spot in the electronic device; and an emissive portion in the interior surface including an area non-overlapping a hot spot.

This application claims the benefit of U.S. Provisional Patent Application No. 61/803,052, filed Mar. 18, 2013 and entitled “METHODS AND STRUCTURES FOR THERMAL MANAGEMENT IN AN ELECTRONIC DEVICE” by WEBER, et al., which is incorporated herein by reference in its entirety for all purposes.

### FIELD OF THE DESCRIBED EMBODIMENTS

The described embodiments relate generally to thermal management of electronic devices. More particularly, embodiments in the present disclosure relate to methods and structures for coating and treating surfaces in the casing of electronic devices to facilitate heat flux out of and prevent heat flux into the device.

### BACKGROUND

In the field of electronic devices, and in particular hand held electronic devices, much progress has been achieved in the last few years. Added capabilities an improved energy efficiency have resulted in devices operating for long periods of time, often in outdoors conditions, exposed to the elements, such as sun light. As a result, an emerging problem is the increased heating of the devices to a point beyond normal temperature operating conditions. An approach is to automatically turn devices ‘off’ when the temperature inside the device reaches a threshold value. However, under current trends, turning ‘off’ conditions are encountered with increased frequency, lasting longer periods of time. Automatic turn ‘off’ may result in undesirable usage interruption, increasing user frustration. Even when the device is able to operate at an increased temperature, there remains a general discomfort for the user to handle an overheated casing.

In some approaches, such as in laptop computers, electrically powered cooling devices may be coupled to the most prominent heat sources in an electronic device to avoid overheating. However, these approaches typically consume extra energy, increase the demand for sensors and extra circuitry in the device layout, and ultimately end up distributing heat to other portions of the electronic device, as the added circuitry also generates heat.

Therefore, what are desired is a structure and a method of forming the structure for thermal management in an electronic device formed of passive components.

### SUMMARY OF THE DESCRIBED EMBODIMENTS

According to embodiments disclosed herein a structure for thermal management in an electronic device may include a casing; a cover glass and a multilayer film on an exterior surface of the casing and of the cover glass. The multilayer film is adapted to reflect radiation in a first spectral region comprising a peak of a solar radiation intensity spectrum. Furthermore, the multilayer film may also be adapted to transmit radiation in a second spectral region comprising a peak of a thermally generated radiation. Thus, a casing and a cover glass consistent with the present disclosure reduces heating of the device due to the absorption of solar radiation while facilitating internally generated heat to be transferred out of the device

In embodiments consistent with the present disclosure, a casing for a portable electronic device may include a multilayer film on an exterior surface of the casing and of a cover glass included in the casing. The multilayer film is adapted to reflect radiation in a first spectral region; and to transmit radiation in a second spectral region. Furthermore, the casing may include a reflective portion in an interior surface such that the reflective portion includes a hot spot in the electronic device. The interior surface of the casing may also include an emissive portion in the interior surface including an area non-overlapping the hot spot.

According to embodiments disclosed herein a method of forming a structure for thermal management in an electronic device may include determining a hot spot area inside a casing of the electronic device. When the hot spot is found, the method includes placing a reflective surface on the hot spot area and forming a high emissivity surface in an interior portion of the casing non-overlapping the hot spot area. The method also includes forming a multilayer film in an exterior surface of the casing.

Other aspects and advantages of the invention will become apparent from the following detailed description taken in conjunction with the accompanying drawings which illustrate, by way of example, the principles of the described embodiments.

### BRIEF DESCRIPTION OF THE DRAWINGS

The described embodiments may be better understood by reference to the following description and the accompanying drawings. Additionally, advantages of the described embodiments may be better understood by reference to the following description and accompanying drawings. These drawings do not limit any changes in form and detail that may be made to the described embodiments. Any such changes do not depart from the spirit and scope of the described embodiments.

FIG. 1 illustrates a perspective view of an electronic device including a coating for thermal management, according to some embodiments.

FIG. 2A illustrates a spectral profile of a multilayer film for thermal management in an electronic device, according to some embodiments.

FIG. 2B illustrates a spectral profile of a multilayer film for thermal management in an electronic device, according to some embodiments.

FIG. 3 illustrates a perspective view of an interior portion of a casing for thermal management of an electronic device, according to some embodiments.

FIG. 4 illustrates a cross-sectional view of a casing for thermal management of an electronic device, according to some embodiments.

FIG. 5 illustrates a cross sectional view of a coating for thermal management of an electronic device, according to some embodiments.

FIG. 6 illustrates a flow chart for a method to form a structure for thermal management in an electronic device, according to some embodiments.

In the figures, elements having the same or similar reference numerals include the same or similar structure, use, or correspond to a similar step or procedure.

### DETAILED DESCRIPTION OF SELECTED EMBODIMENTS

Representative applications of methods and apparatus according to the present application are described in this section. These examples are being provided solely to add context and aid in the understanding of the described embodiments. It will thus be apparent to one skilled in the art that the described embodiments may be practiced without some or all of these specific details. In other instances, well known process steps have not been described in detail in order to avoid unnecessarily obscuring the described embodiments. Other applications are possible, such that the following examples should not be taken as limiting.

In the following detailed description, references are made to the accompanying drawings, which form a part of the description and in which are shown, by way of illustration, specific embodiments in accordance with the described embodiments. Although these embodiments are described in sufficient detail to enable one skilled in the art to practice the described embodiments, it is understood that these examples are not limiting; such that other embodiments may be used, and changes may be made without departing from the spirit and scope of the described embodiments.

In current electronic device applications, such as handheld and portable devices having wireless and radio-frequency (RF) circuits, miniaturization of electronic circuitry and increase in component density has led to overheating and the need to reduce the device temperature. In handheld devices, strategies for heat dissipation as disclosed herein may include the inward and outward flux of electromagnetic radiation. Thus, in some embodiments, a heat management strategy may include structures that reflect incoming electromagnetic radiation, preventing it from entering the device and being absorbed by components therein. In some embodiments, a heat management strategy may include structures in an interior portion of the device having an optimized physical composition that enables out flux of thermally generated electromagnetic radiation into the environment.

When considering thermal management for handheld electronic devices the interaction of the device with its environment is paramount. For thermal management purposes, two main sources of heat may be readily identified: the sun; and the electronic circuitry inside the device. The sun is an external source of heat, and the electronic circuitry inside the device is an internal source of heat. Typically, the sun is a most effective heater in the near infrared region of the spectrum (from about 800 nm to about 1500 nm), while internal heat generation in the radio-frequency (RF) electronics of the device occurs at longer wavelengths, such as the infrared region (larger than 2000 nm). Accordingly, embodiments in the present disclosure include methods and structures that take into account different configuration and different wavelength regions of heat sources in an electronic device to avoid an unbalanced influx of heat with the consequent temperature rise of the device.

In current electronic device applications, especially in the case of handheld devices that are used for extensive periods of time in an outdoor environment, overheating issues become a problem. Most devices include a casing structure typically made out of a metal, which has a high thermal conductivity. Typically, the materials and structures used in handheld electronic devices are light weight and provide usage comfort, and also provide radio-frequency RF insulation to portions of the device. As a result, materials and structures used for handheld electronic devices have a tendency to absorb solar infrared radiation. Moreover, the heat generated internally is not efficiently coupled out of the device.

Therefore, in order to reduce the adverse impact of an external source of heat, such as the Sun, a reflective layer can be used to cover the entirety or a portion of an exterior surface of an electronic device casing. The reflective layer may reflect incoming solar radiation for a first spectral region. The first spectral region being such that high absorption by components in the electronic device including the casing may be expected, in the absence of the reflective layer. In addition, to facilitate heat flow outside of the electronic device, the reflective layer may provide a high transmission in a second spectral region including a portion of the spectrum of radiation thermally generated by the electronic circuitry inside the device. These and other embodiments will be described in detail below, with reference to the following figures.

FIG. 1 illustrates a perspective view of an electronic device 100 including a coating 150 for thermal management, according to some embodiments. FIG. 1 illustrates a solar radiation 20 generated by the sun, which impinges on device 100. Electronic device includes a casing 110 and a cover glass 120. Coating 150 may be a multilayer film reflecting a portion of solar radiation 20. Multilayer film may include a stack including a dielectric layer having a high index of refraction adjacent to a dielectric layer having a low index of refraction. Accordingly, multilayer film 150 may include a band pass filter or a band-block filter efficiently reflecting solar radiation 20 in a first spectral region. Accordingly, the first spectral region is selected such that it includes solar radiation that would be absorbed efficiently by device 100 in the absence of coating 150, generating undesirable heat. In some embodiments, the first spectral region includes a bandwidth in the near Infrared (NIR) domain. For example, in some embodiments the first spectral region includes a bandwidth from a first wavelength at about 800 nm to a second wavelength at about 1500 nm. For example, the first spectral region may be selected to include a portion of solar radiation 20 that is absorbed up to 95% or higher, by the electronic device in the absence of multilayer film 150. Moreover, in embodiments consistent with the present disclosure multilayer film 150 may be transparent to electromagnetic radiation outside of the first spectral region. In particular, in some embodiments, multilayer film 150 may have a high transmittance value for electromagnetic radiation in a wavelength region including wavelengths larger than 2000 nm.

FIG. 1 also shows an internal radiation 30 thermally generated by the RF circuitry, batteries, and other active components in electronic device 100. Internal radiation 30 typically includes radiation in long wavelength regions of the spectrum, larger than 2500 nm. More specifically, internal radiation 30 may include radiation in a wavelength region with wavelengths longer than 2000 nm. Accordingly, in embodiments consistent with the present disclosure multilayer film 150 may have a high transparency in regions of the spectrum including internal radiation 30. Thus, multilayer film 150 allows the transit of thermally generated internal radiation 30 from inside to outside of device 100, through casing 110.

FIG. 2A illustrates a spectral profile 250t of a multilayer film 150 for thermal management in an electronic device, according to some embodiments. Spectral profile 250t may be a transmittance of incident radiation impinging upon multilayer film 150. In FIG. 2A, the ordinate axis represents a transmittance value in arbitrary units, and the abscissa represents a wavelength value, in arbitrary units. In some configurations it is convenient to describe transmittance in percentage (of incoming radiation) and wavelength in nano-meters (1 nm=10⁻⁹ m). FIG. 2A includes a high transmittance value 252 (T₂) for portions of the spectrum below a first wavelength 261 (λ₁). FIG. 2A also shows a low transmittance value 251 (T₁) for portions of the spectrum including radiation at wavelengths between λ₁ 261 and a second wavelength 262 (λ₂). In some embodiments, multilayer film 150 may have value T₂ 251 for portions of the spectrum above second wavelength 262 (λ₂).

FIG. 2A also illustrates exemplary radiation spectra 220 and 230. Radiation spectra 220 and 230 have the same abscissa (wavelength) as spectral profile 250t, and an ordinate representing intensity (in arbitrary units) to the right. Spectrum 220 may represent incoming solar radiation 20, and spectrum 230 may represent internal radiation 30 (cf. FIG. 1). In some embodiments spectral profile 250t of multilayer film 150 may be selected to have transmittance 251 (T₁) where spectrum 220 has peak intensity.

One of ordinary skill in the art will recognize that specific values for T₁ and T₂ may depend on the application and environmental conditions of the electronic device. For example, in some embodiments a high transmittance 252 (T₂) may be as high as about 70%, 80%, 90% or more. In some embodiments a high transmittance 252 (T₂) may be close to 100%, such as 99.9% or even closer. Also, low transmittance 251 may be a value such as 10%, or less. For example, in some embodiments, low transmittance 251 may be close to 0%, such as 1% or less. One of ordinary skill will recognize that the specific values of first wavelength 261 and of second wavelength 262 are also non-limiting, depending on the specific application for electronic device 100.

FIG. 2B illustrates a spectral profile 250r of a multilayer film for thermal management in an electronic device, according to some embodiments. Spectral profile 250r may be a reflectivity spectrum for multilayer film 150. For comparison, FIG. 2B also illustrates spectral profile 250t superimposed with spectral profile 250r. Accordingly, the abscissa of spectral profiles 250t and 250r is the same (Wavelength), and the ordinate of spectral profile 250r is a reflection coefficient, shown to the right in FIG. 2B. The reflection coefficient in the ordinate of spectral profile 250r may be given in percent values. Thus, in embodiments consistent with the present disclosure, for a given point in profile 250t having ordinate T (% transmission), a corresponding point at the same wavelength in spectral profile 250r may have ordinate R (% reflection) given approximately as

R=100−T (1)

More generally, a multilayer film 150 consistent with the present disclosure has a low transmission in spectral regions of high reflectivity. Likewise, a multilayer film 150 consistent with the present disclosure has a high transmission in spectral regions of low reflectivity. For example, in spectral regions where curve 250t shows a high transmittance T₂, curve 250r may show a low reflectance 271 (R₁). Likewise, in spectral regions where curve 250t shows a low transmittance T₁, curve 250r may show a high reflectance 272 (R₂).

By reference to FIG. 2A, in some embodiments a region of high transmission and low reflectivity for multilayer film 150 may overlap with a peak intensity of curve 230. Likewise, a region of low transmission and high reflectivity for multilayer film 150 may overlap with a peak intensity of curve 220. Accordingly, a sum of the ordinates in curve 250t (% transmission) and the ordinates in curve 250r (% reflectivity) is approximately equal to 100% for the entire spectral range depicted in FIGS. 2A and 2B (cf. Eq. (1)).

FIG. 3 illustrates a perspective view of an interior portion 320 of a casing 110 for thermal management of an electronic device 100, according to some embodiments. Interior portion 320 may include a reflective portion 310 coated with a high reflectivity material. Reflective portion 310 may include a portion inside electronic device 100 where a hot-spot is identified. For example, reflective portion 310 may include a mounting for a high speed processing circuit where much heat is dissipated. The circuit may be mounted on a printed circuit board (PCB) in close proximity with reflective portion 310. The high reflectivity material coating reflective portion 310 may be aluminum, silver, gold, copper, or any other material having a high reflectivity across multiple spectral regions. In particular, reflective portion 310 may have a high reflectivity in spectral regions having a wavelength greater than second wavelength 262 (cf. FIG. 2). Inside portion 320 in FIG. 3 also includes an emissive portion 330 that is non-overlapping with a hot spot. Accordingly, emissive portion 330 may not be in direct contact with circuitry or components of device 100 having high heat dissipation. For example, heat inside device 100 may reach emissive portion 330 through convection or conduction from a hot spot. However, the amount of heat transferred to emissive portion 330 from a hot spot inside electronic device 100 through electromagnetic radiation may be marginal. In some embodiments, emissive portion 330 includes an interior surface 331 formed as a black body radiator having emissivity of one, or as close as possible to one. For example, surface 331 may be anodized to form a rugged surface having a black color, enhancing emissivity. The black or dark color may be provided by a layer of paint, or simply by a thin oxide layer formed at surface 331. In embodiments where the material in casing 110 is aluminum, anodization of emissive portion 330 may result in a layer of aluminum oxide formed at surface 331.

Accordingly, when electronic device 100 has been in a prolonged operation and heats up to a certain temperature, reflective portion 310 and emissive portion 330 may be at similar temperatures. While reflective portion 310 is located in close proximity to a hot spot, thermal radiation 30 generated within the hot spot will be reflected off of the surface of reflective portion 310 and transmitted outside of casing 110. Thus, structures in embodiments consistent with the present disclosure facilitate the flow of thermal energy out of electronic device 100 into the environment. For example, in some embodiments the wall of casing 110 opposite portion 310 may include a transparent window (e.g., cover glass 120, cf. FIG. 1), such that internal radiation 30 from reflective portion 310 may exit casing 110. By releasing thermal energy from interior portion 320 of casing 110 into the environment, structures consistent with the present disclosure reduce thermal stress in electronic device 100. For example, under regular operating conditions the equilibrium temperature in interior 320 of casing 110 may be reduced compared to the equilibrium temperature of prior art electronic devices.

FIG. 4 illustrates a cross-sectional view of casing 110 for thermal management of an electronic device 100, according to some embodiments. Casing 110 includes multilayer film 150 on the exterior portion. FIG. 4 also illustrates reflective portion 310 and emissive portion 330 in interior portion 320 of casing 110. Casing 110 also includes cover glass 120 having an exterior surface coated with multilayer film 150, and an uncoated interior surface, according to some embodiments.

As shown in FIG. 4, cover glass 120 allows internal radiation 30 reflected from reflective portion 310 to pass through and be transmitted outside of electronic device 100. Accordingly, internal radiation 30 reflected off of reflective portion 310 may be generated by circuitry included in printed circuit board (PCB) 410. A point 411 in emissive portion 330 may emit internal radiation 30 in all directions. Accordingly, a portion of internal radiation 30 emitted through emissive surface 331 may be more intense than a portion of internal radiation 30 emitted through a surface opposite to surface 331. In some embodiments, intensity of internal radiation 30 reflected off of reflective surface 310 may be more intense than internal radiation 30 emitted from surface 331 of emissive portion 330.

FIG. 4 also shows solar radiation 20 reflected off of the exterior surface of casing 110. Solar radiation 20 is reflected by multilayer film 150, which may be designed to provide transmission and reflection curves as described in detail above (e.g., curves 250t and 250r, cf. FIGS. 2A and 2B). Thus, embodiments of electronic device 100 as illustrated in FIG. 4 reduce absorption of solar radiation 20 and maximize the transmission of thermally generated internal radiation 30. Accordingly, the heat influx from outside sources is reduced, and the heat out flux from internal sources is increased. In consequence, the thermal equilibrium of electronic device 100 with the environment occurs at a lower temperature as compared to the prior art, according to embodiments disclosed herein.

FIG. 5 illustrates a cross sectional view of coating 150 for thermal management of an electronic device, according to some embodiments. Accordingly, coating 150 may be a multilayer film forming a band pass filter, or a band block filter. Multilayer film 150 may be a band pass filter having transmission and reflection spectral properties as described in detail above (e.g., curves 250t and 250r, cf. FIGS. 2A and 2B). In some embodiments, multilayer film 150 is formed of a plurality ‘k’ of thin film layers 510-1, 510-2, up to 510-k, collectively referred to hereinafter as thin film layers 510. Each layer 510-i has a thickness dᵢ and a refractive index iₙ, where ‘i’ is any integer from 1 to ‘k.’ the value of integer ‘k’ may be any number to obtain a desired transmission and reflection spectrum. Also, the thicknesses and index of refraction of each thin layer (dᵢ, iₙ) may be selected accordingly. FIG. 5 illustrates incident radiation 501 impinging upon the top surface of multilayer film 150. As a result of the optical properties of multilayer film 150 a reflected radiation 502 bounces off of multilayer film 150, and a transmitted radiation 503 goes through multilayer film 150. Accordingly, the spectral properties of reflected radiation 502 and transmitted radiation 503 may be determined by transmission and reflection curves as described in detail above (e.g., curves 250t and 250r, cf. FIGS. 2A and 2B). The choice of incident radiation 501 impinging on the top portion of multilayer film 150 is arbitrary. One of ordinary skill in the art will recognize that the spectral properties of reflected radiation 502 and transmitted radiation 503 will be substantially the same, regardless of whether incident radiation 501 impinges on a top surface or on a bottom surface of multilayer film 150.

Incident radiation 501, reflected radiation 502, and transmitted radiation 503 may have spectral characteristics following Eq. (1) wherein the value T may be a percent ratio of intensity in transmitted radiation 503 to intensity in incident radiation 501. And the value R in Eq. (1) may be the percent ratio of intensity in reflected radiation 502 to intensity in incident radiation 501. While the mathematical relation in Eq. (1) may not be satisfied exactly in some embodiments, Eq. (1) may be satisfied approximately, except for a small portion of absorbed incident radiation. Accordingly, incident beam 501 may be either substantially reflected into reflected beam 502 or substantially transmitted into transmitted beam 503. For example, the portion of an incident beam impinging upon multilayer film 150 being absorbed within the film may be very low. In some embodiments, it is desired that the portion of incident beam impinging upon multilayer film 150 be close to zero, or zero.

In some embodiments, thin layers 510 are formed of dielectric materials deposited using well known techniques such as sputtering or vapor deposition. In some embodiments, layers 510 form an alternating sequence of a dielectric layer having a high index of refraction adjacent to a dielectric layer having a low index of refraction. For example, a dielectric layer 510 may include alternating layers of titanium oxide (TiO₂) and layers of silicon oxide (SiO₂). In that regard, TiO₂, has a refractive index of approximately 2.6 at visible wavelengths of approximately 588 nm, and an index of refraction generally above 2.4 for wavelengths in the NIR region from about 800 nm to about 1500 nm. By the same token, SiO2 has a refractive index of about 1.54 at a visible wavelength of approximately 588 nm, and an index of refraction lower than about 1.54 for wavelengths in the NIR from about 800 nm to about 1500 nm. Some embodiments may include a dielectric layer formed of magnesium oxide (MgO), which has an index of refraction of approximately 1.74 at visible wavelengths close to 588 nm, and an index of refraction between 1.74 and 1.7 for wavelengths in the NIR region from about 800 nm to about 1500 nm. One of ordinary skill will recognize that any other combination of dielectric materials may be used to form multilayer film 150.

FIG. 6 illustrates a flow chart for a method 600 to form a structure for thermal management in an electronic device, according to some embodiments. The electronic device may include a casing and a cover glass (e.g., electronic device 100, casing 110, cover glass 120, cf. FIG. 1). The casing may have an exterior portion and an interior portion (e.g., interior portion 320, cf. FIG. 3). Accordingly, method 600 may result in a multilayer film coating the entirety of the exterior portion of the casing (e.g., multilayer film 150, cf. FIG. 1). In some embodiments, method 600 may result in a partial coverage of the exterior portion of the casing by the multilayer film.

Step 610 may include determining the location and spatial distribution of hot spot areas inside the casing. For example, step 610 may include finding an area of the casing overlapping an area where a high power circuit is located in the electronic device. In some embodiments, step 610 includes finding an area directly underneath or above an RF circuit or a digital signal processor in the electronic device.

Step 620 may include placing a reflective surface in the interior portion of the casing corresponding to the location and spatial distribution of the hot spot areas determined in step 610. In some embodiments, step 620 may include sputtering a high reflectivity material on a portion of the interior portion of the casing directly above or below a hot spot area. The high reflectivity material may be a conducting material such as aluminum, gold, copper, or any other high reflectivity material. One of ordinary skill will recognize that many techniques are available for forming a high reflectivity layer in step 620. For example, vapor deposition techniques may be used in step 620, in combination with a mask to cover areas of the interior of the casing where coating is not desired (e.g., areas non-overlapping hot spot areas).

Step 630 may include forming a high emissivity surface in the interior portion of the casing corresponding to areas non-overlapping hot spot areas. Accordingly, step 630 may include forming a surface having black body emissivity close to one (1) on areas of the interior of the casing not directly above or below a hot spot area (e.g., surface 331, cf. FIGS. 3 and 4). In some embodiments, step 630 may include forming a thin oxide layer on the interior surface of the casing. For example, step 630 may include an anodization step on a metal surface. In some embodiments, step 630 may include partially or totally coating the interior surface of the casing with a layer of black paint.

Step 640 may include forming a multilayer film outside the casing. Accordingly, in some embodiments step 640 may include alternating thin layers of dielectric materials having a high index of refraction and a low index of refraction. In that regard, step 640 may include forming a multilayer film that reflects radiation preferentially in a first spectral region, and transmits radiation in a second spectral region. The first spectral region may be as the region included between wavelengths λ₁ and λ₂, described in detail above in reference to FIG. 2A. In some embodiments, step 640 may include selecting the first spectral region by selecting a wavelength region in the spectrum of solar radiation (e.g., solar radiation 20 and spectrum 220, cf. FIGS. 1 and 2A) that is highly absorbed by an electronic device without the multilayer film coating. For example, selecting the first spectral region may include selecting a wavelength region in a solar absorption spectrum wherein the absorbance is larger than a pre-determined value. In some embodiments the pre-determined value may be as high as 95%. In some embodiments, the pre-determined value may be lower than 95%, such as 90%, 85%, or even lower. One of ordinary skill will recognize that the particular selection of the pre-determined value may vary according to specific applications of the electronic device. Moreover, in some embodiments the pre-determined value may be selected according to the geographical region of use of the electronic device. For example, near a tropical region the pre-determined value selected in step 640 may be lower than the pre-determined value selected near a polar region, or in a region far from the tropics, or in a region where solar radiation is not too intense throughout the year.

The various aspects, embodiments, implementations or features of the described embodiments can be used separately or in any combination. Various aspects of the described embodiments can be implemented by software, hardware or a combination of hardware and software. The described embodiments can also be embodied as computer readable code on a computer readable medium for controlling manufacturing operations or as computer readable code on a computer readable medium for controlling a manufacturing line. The computer readable medium is any data storage device that can store data which can thereafter be read by a computer system. Examples of the computer readable medium include read-only memory, random-access memory, CD-ROMs, HDDs, DVDs, magnetic tape, and optical data storage devices. The computer readable medium can also be distributed over network-coupled computer systems so that the computer readable code is stored and executed in a distributed fashion.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of specific embodiments are presented for purposes of illustration and description. They are not intended to be exhaustive or to limit the described embodiments to the precise forms disclosed. It will be apparent to one of ordinary skill in the art that many modifications and variations are possible in view of the above teachings.

What is claimed is:

1. A structure for thermal management in an electronic device, the structure comprising:
a casing;
a cover glass;
a multilayer film on an exterior surface of the casing and of the cover glass; wherein
the multilayer film is adapted to reflect radiation in a first spectral region comprising a peak of a solar radiation intensity spectrum; and
the multilayer film is adapted to transmit radiation in a second spectral region comprising a peak of a thermally generated radiation.

2. The structure of claim 1 wherein the multilayer film comprises an alternating stack including a dielectric layer having a high index of refraction adjacent to a dielectric layer having a low index of refraction for wavelengths in the first spectral region and the second spectral region.

3. The structure of claim 1 wherein the first spectral region and the second spectral region are non-overlapping.

4. The structure of claim 1 wherein the thermally generated internal radiation comprises radiation generated by heat produced by a radio-frequency circuit.

5. The structure of claim 1 wherein the first spectral region comprises a wavelength region from a first wavelength to a second wavelength; and
the second spectral region comprises a wavelength region with wavelengths larger than the second wavelength.

6. The structure of claim 5 wherein the first wavelength is about 800 nm and the second wavelength is about 1500 nm.

7. The structure of claim 1 wherein the casing comprises a reflective portion including a hot spot and an emissive portion non-overlapping the hot spot in an interior surface.

8. The structure of claim 7 wherein the reflective portion and the emissive portion are optimized for a region of the spectrum comprising the second spectral region.

9. A casing for a portable electronic device, comprising:
a multilayer film on an exterior surface of the casing and of a cover glass; wherein
the multilayer film is adapted to reflect radiation in a first spectral region; and
the multilayer film is adapted to transmit radiation in a second spectral region;
a reflective portion in an interior surface including a hot spot in the electronic device; and
an emissive portion in the interior surface including an area non-overlapping a hot spot.

10. The casing of claim 9 wherein the first spectral region comprises a peak of a solar radiation intensity spectrum; and
the second spectral region comprises a peak of a thermally generated internal radiation.

11. The casing of claim 9 wherein the multilayer film comprises an alternating stack including a dielectric layer having a high index of refraction for wavelengths in the first and second spectral regions, adjacent to a dielectric layer having a low index of refraction for wavelengths in the first and in second spectral regions.

12. A method of forming a structure for thermal management in an electronic device, the method comprising:
determining a hot spot area inside a casing of the electronic device;
placing a reflective surface on the hot spot area;
forming a high emissivity surface in an interior portion of the casing non-overlapping the hot spot area; and
forming a multilayer film in an exterior surface of the casing.

13. The method of claim 12 wherein forming a multilayer film comprises increasing the reflectivity of the multilayer film in a first spectral region and increasing the transmission of the multilayer film in a second spectral region.

14. The method of claim 13 wherein increasing the reflectivity of the multilayer film in a first spectral region comprises increasing the reflectivity in a wavelength region from about 800 nm to about 1500 nm.

15. The method of claim 13 wherein increasing the transmission of the multilayer film in a second spectral region comprises increasing the transmission of the multilayer film in a wavelength region larger than 2000 nm.

16. The method of claim 12 wherein forming a multilayer film comprises alternating a layer of a dielectric material having a high refractive index with a layer of dielectric material having a low refractive index.

17. The method of claim 16 wherein alternating thin layers of dielectric materials comprises forming a layer of titanium oxide; and
forming a layer of silicon oxide adjacent to the layer of titanium oxide.

18. The method of claim 12 wherein forming a high emissivity surface in an interior portion of the casing comprises forming a layer of a metal oxide on the surface of the material.

19. The method of claim 12 wherein determining a hot spot area comprises selecting an area overlapping a circuit that generates heat during prolonged operation.

20. The method of claim 12 wherein determining a hot spot area comprises selecting an area overlapping a radio-frequency (RF) circuit in the electronic device.
